(19) United States
(12) Patent Application Publication
(10) Pub. No.: US 2024/0297277 A1
(43) Pub. Date: Sep. 5, 2024

(54) LIGHT-EMITTING DEVICE

(71) Applicant: TOYODA GOSEI CO., LTD., Kiyosu-shi (JP)

(72) Inventor: Yoshiki TANIYAMA, Kiyosu-shi (JP)

(21) Appl. No.: 18/421,329

(22) Filed: Jan. 24, 2024

(30) Foreign Application Priority Data
Mar. 1, 2023 (JP) 2023-031263

(51) Int. Cl. H01L 33/58

(52) U.S. Cl. CPC H01L 33/58

(57) ABSTRACT

A light-emitting device includes a light-emitting element mounted on a substrate, a lens disposed on the substrate so as to cover the light-emitting element, and a sealing liquid disposed in a space defined under the lens to seal the light-emitting element. An inner surface of the lens includes a depression that is recessed upward at a position not overlapping an optical axis of the light-emitting element. A position of the depression is higher than a position of a point on the inner surface that is located on the optical axis. A height of the inner surface monotonically increases from the point on the optical axis to the depression.

### CROSS-REFERENCE TO RELATED APPLICATIONS

The present patent application claims the priority of Japanese patent application No. 2023/031263 filed on Mar. 1, 2023, and the entire contents of Japanese patent application No. 2023/031263 are hereby incorporated by reference.

### TECHNICAL FIELD

The present invention relates to a light-emitting device.

### BACKGROUND ART

A light-emitting module is known in which a light-emitting element is sealed in a liquid (see, e.g., Patent Literature 1). In the light-emitting module of Patent Literature 1, the inner space of a package is filled with the liquid to seal the light-emitting element.

### CITATION LIST

### Patent Literatures

Patent Literature 1: JP 2016/207754 A

### SUMMARY OF INVENTION

In case of the light-emitting module of Patent Literature 1, however, it is not easy to completely fill the inner space of the package with the liquid and air bubbles may be mixed in. Then, light emitted from the light-emitting element can be totally reflected at the interface between the air bubbles and the liquid, hence, light extraction efficiency decreases when the air bubbles are located directly above the light-emitting element.

It is an object of the invention to provide a light-emitting device in which a light-emitting element is sealed with a liquid and which can suppress a decrease in light extraction efficiency due to air bubbles included in the liquid.

According to an aspect of the invention, provided is a light-emitting device as defined below.

(1) A light-emitting device, comprising:
a light-emitting element mounted on a substrate;
a lens disposed on the substrate so as to cover the light-emitting element; and
a sealing liquid disposed in a space defined under the lens to seal the light-emitting element,
wherein an inner surface of the lens comprises a depression that is recessed upward at a position not overlapping an optical axis of the light-emitting element,
wherein a position of the depression is higher than a position of a point on the inner surface that is located on the optical axis, and
wherein a height of the inner surface monotonically increases from the point on the optical axis to the depression.

(2) The light-emitting device defined in (1), wherein an air bubble is included in at least a portion of the depression.

(3) The light-emitting device defined in (1) or (2), wherein the sealing liquid comprises a fluorine-based oil.

(4) The light-emitting device defined in (1) or (2), wherein the depression is provided in a position where horizontal position thereof does not overlap the light-emitting element.

(5) The light-emitting device defined in (1) or (2), wherein the depression comprises an annular planar pattern that surrounds the optical axis.

(6) The light-emitting device defined in (1) or (2), wherein the inner surface of the lens comprises a protrusion located at a position overlapping the optical axis and curved toward the light-emitting element.

### Advantageous Effects of Invention

According to an embodiment of the invention, it is possible to provide a light-emitting device in which a light-emitting element is sealed with a liquid and which can suppress a decrease in light extraction efficiency due to air bubbles included in the liquid.

### BRIEF DESCRIPTION OF DRAWINGS

FIG. 1A is a vertical cross-sectional view showing a light-emitting device in an embodiment of the present invention.

FIG. 1B is an example of cross-sectional view showing the light-emitting device shown in FIG. 1A taken along line A-A.

FIG. 2 is a vertical cross-sectional view showing a light-emitting device as Comparative Example that includes a lens having a normal shape.

FIGS. 3A and 3B are diagrams illustrating other examples of a plane pattern of a depression.

FIG. 4A is a vertical cross-sectional view showing the light-emitting device when the depression has a planar pattern with low symmetry.

FIGS. 4B and 4C are examples of cross-sectional view showing the light-emitting device shown in FIG. 4A taken along line B-B.

### DESCRIPTION OF EMBODIMENTS

### (Configuration of a Light-Emitting Device)

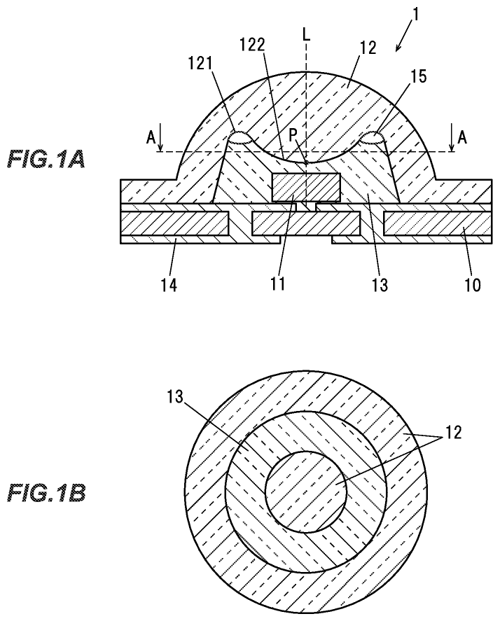

FIG. 1A is a vertical cross-sectional view showing a light-emitting device 1 in an embodiment of the invention. FIG. 1B is an example of cross-sectional view showing the light-emitting device 1 shown in FIG. 1A taken along line A-A.

The light-emitting device 1 includes a light-emitting element 11 mounted on a substrate 10, a lens 12 disposed on the substrate 10 so as to cover the light-emitting element 11, and a sealing liquid 13 disposed in a space defined under the lens 12 to seal the light-emitting element 11.

In the light-emitting device 1, an inner surface of the lens 12 has a depression 121 that is recessed upward at a position not overlapping an optical axis L of the light-emitting element 11. At least the horizontal position of the apex (the highest point) of the depression 121 does not overlap the optical axis L. The depression 121 serves as a pocket to accommodate air bubbles 15 included in the sealing liquid 13. That is, when the air bubbles 15 are included in the sealing liquid 13, the air bubbles 15 are accommodated in at least a portion of the depression 121.

Since the depression 121 is located at the position not overlapping the optical axis L of the light-emitting element 11, the air bubbles 15 accommodated in the depression 121 are also located at the position not overlapping the optical axis L of the light-emitting element 11. Here, the optical axis L is an axis pointing in a direction in which light emission intensity of the light-emitting element 11 is strongest, and it is usually an axis passing through the center of the light-emitting element 11 and pointing in a direction perpendicular to a main surface of the substrate 10.

As shown in FIG. 1A, the position of the depression 121 is higher than the position of a point P on the inner surface of the lens 12 that is a point located on the optical axis L. In addition, the height of the inner surface of the lens 12 monotonically increases from the point P on the optical axis L to the depression 121. The monotonic increase here is monotonic increase in a broad sense, and the height of the inner surface does not decrease even once from the point P on the optical axis L to the depression 121. That is, when the horizontal distance from the point P on the optical axis L to the depression 121 is defined as x and the height of the inner surface of the lens 12 is defined as f(x), and if x₁<x₂ then f(x₁)≤f(x₂) holds true. Therefore, the air bubbles 15 included in the sealing liquid 13 move to the depression 121 without staying in the vicinity of the optical axis L of the light-emitting element 11 due to buoyancy, and are accommodated in the depression 121.

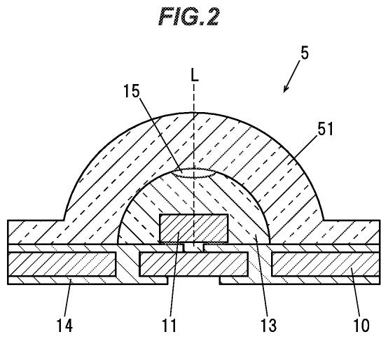

FIG. 2 is a vertical cross-sectional view showing a light-emitting device 5 as Comparative Example that includes a lens 51 having a normal shape. As shown in FIG. 2, a space located inside the lens 51 and housing the sealing liquid 13 has a dome shape.

Therefore, the air bubbles 15 included in the sealing liquid 13 easily move to the center of the space inside the lens 51 due to buoyancy. This result in that the air bubbles 15 are located in the vicinity of the optical axis L of the light-emitting element 11, hence, light emitted from the light-emitting element 11 in a direction around the optical axis L is reflected at the interface between the sealing liquid 13 and the air bubbles 15 and light extraction efficiency of the light-emitting device 5 thereby decreases.

In the light-emitting device 5 shown in FIG. 2, light emitted from the light-emitting element 11 in a direction around the optical axis L is extracted to the outside through the sealing liquid 13, the air bubbles 15, and the lens 51. Since the refractive index of the air bubbles 15 is as low as 1.0, total reflection may occur at the interface between the air bubbles 15 and the sealing liquid 13 having a higher refractive index than the air bubbles 15.

On the other hand, in the light-emitting device 1 in the embodiment of the invention, since the air bubbles 15 are accommodated in the depression 121, the air bubbles 15 do not overlap the optical axis L and light emitted from the light-emitting element 11 in a direction around the optical axis L passes through the sealing liquid 13 and the lens 12 without passing through the air bubbles 15 and is extracted to the outside. Therefore, a decrease in light extraction efficiency due to the air bubbles 15 can be suppressed.

When, e.g., fluorine-based oils with a refractive index of 1.3 are used as the material of the sealing liquid 13 and quartz with a refractive index of 1.5 is used as the material of the lens 12, total reflection does not occur at the interface between the sealing liquid 13 and the lens 12 because the refractive index of the sealing liquid 13 is smaller than that of the lens 12, and the reflection rate is small because the difference in refractive index between the two is small. This allows light to be extracted with high efficiency.

More preferably, the depression 121 is provided in a position where its horizontal position does not overlap the light-emitting element 11 (a position where at least the horizontal position of the apex of the depression 121 does not overlap the light-emitting element 11). Thus, the horizontal position of the air bubbles 15 accommodated in the depression 121 does not overlap the light-emitting element. As a result, the decrease in light extraction efficiency due to the air bubbles 15 can be suppressed more effectively.

The horizontal cross-sectional shape of the sealing liquid 13 shown in FIG. 1B corresponds to the planar pattern of the depression 121. The planar pattern of the depression 121 is a circular annular shape in the example shown in FIG. 1B, but the planar pattern of the depression 121 is not limited thereto. The planar pattern here means a pattern in a direction parallel to the surface of the substrate 10.

It is considered that even if the sealing liquid 13 enters between the inner surface of the lens 12 (the inner surface of the depression 121) and the air bubbles 15 in a state in which the air bubbles 15 are gathered in the depression 121, light extraction efficiency is usually hardly affected. However, since the air bubbles 15 is located closer to the upper surface of the light-emitting element 11 by the volume of the sealing liquid 13 that has entered between the inner surface of the lens 12 and the air bubbles 15, light extraction efficiency may be affected depending on the amount of the air bubbles 15 between the inner surface of the lens 12 and the air bubbles 15. If the inner surface of the depression 121 has a corner, the sealing liquid 13 may accumulate at the corner due to surface tension and the amount of the sealing liquid 13 entering between the inner surface of the lens 12 and the air bubbles 15 may increase, hence, the shape of the depression 121 in a vertical cross section of the lens 12 is preferably composed of a curved line as shown in FIG. 1A.

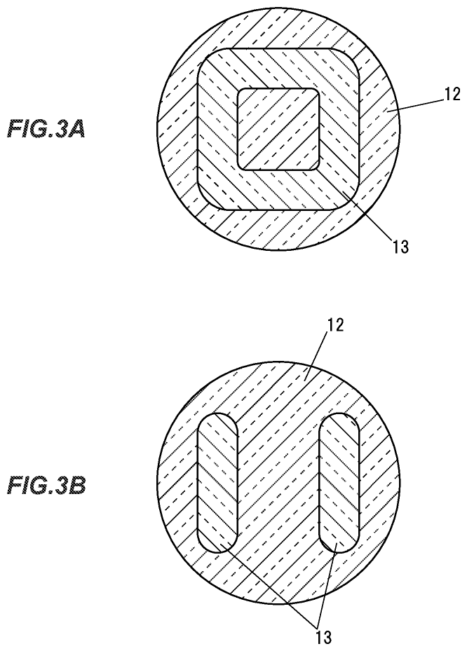

FIGS. 3A and 3B are other examples of cross-sectional view showing the light-emitting device 1 shown in FIG. 1A taken along line A-A, and show other examples of the planar pattern of the depression 121 corresponding to the cross-sectional shape of the sealing liquid 13.

The planar pattern of the depression 121 shown in FIG. 3A is a rectangular annular pattern. The plane pattern of the depressions 121 may be a polygonal annular shape, as is the pattern shown in FIG. 3A. The planar pattern of the depression 121 shown in FIG. 3B is a pattern composed of two parallel straight lines. The planar pattern of the depressions 121 may be a non-annular shape, as is the pattern shown in FIG. 3B.

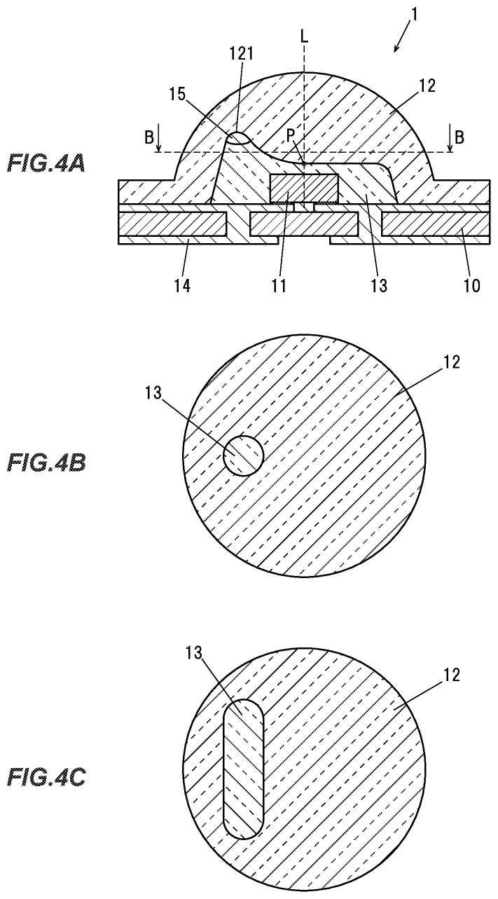

FIG. 4A is a vertical cross-sectional view showing the light-emitting device 1 when the depression 121 has a planar pattern with low symmetry. FIGS. 4B and 4C are examples of cross-sectional view showing the light-emitting device 1 shown in FIG. 4A taken along line B-B.

Both the patterns shown in FIGS. 4B and 4C are not rotationally symmetrical about the center of the lens 12, unlike the patterns shown in FIGS. 1B, 3A, and 3B. In this way, the symmetry of the planar pattern of the depression 121 may be low.

A particularly preferable planar pattern of the depression 121 is an annular pattern surrounding the optical axis L of the light-emitting element 11, as shown in FIG. 1B and FIG. 3A. In this case, the air bubbles 15 included in the sealing liquid 13 can easily enter the depression 121, no matter in which direction the air bubbles 15 move.

The amount of the air bubbles 15 included in the sealing liquid 13 may vary depending on the viscosity of the sealing liquid 13, etc. In a such case, the depth or width, etc., of the depression 121 can be adjusted depending on the viscosity of the sealing liquid 13, etc., so that the air bubbles 15 can be accommodated sufficiently.

It is preferable that a protrusion 122 curved toward the light-emitting element 11 be provided on the inner surface of the lens 12 at a position overlapping the optical axis L of the light-emitting element 11, as shown in FIG. 1A. The protrusion 122 can assist movement of the air bubbles 15 from the vicinity of the optical axis L of the light-emitting element 11 to the depression 121.

The light-emitting element 11 is typically an LED chip. The light emitting element 11 is also typically a flip-chip type element, but may be a face-up type element. The emission wavelength of the light-emitting element 11 is not particularly limited, and may be, e.g., a wavelength in the visible region or a wavelength in the ultraviolet region. The light-emitting element 11 may be a light-emitting element other than LED, such as a laser diode (LD).

The substrate 10 has a wiring 14 formed of Cu, etc., on its surface. The light-emitting element 11, when being a flip-chip type element, is connected to the wiring 14 by a conductive bonding member formed of AuSn or solder, etc.

The outer shape of the lens 12 is typically a dome shape as shown in FIG. 1A, but is not limited thereto. As the material of the lens 12, e.g., quartz, alumina, fluoropolymer, etc. can be used.

The sealing liquid 13 is formed of a liquid transparent to light emitted by the light-emitting element 11, such as fluorine-based oils or water. It is preferable that the sealing liquid 13 also have heat dissipation properties, moisture barrier properties, properties to efficiently introduce light into the lens 12, and properties to hold the lens 12 by surface tension until the lens 12 is fixed to the substrate 10. For example, fluorine-based oils with moisture barrier properties are particularly preferable as the material of the sealing liquid 13.

If the viscosity of the sealing liquid 13 is too high, the air bubbles 15 are less likely to move and it is difficult to make the air bubbles 15 move to the depression 121. Therefore, the viscosity of the sealing liquid 13 is preferably not more than 1000 Pa·Sec.

A typical procedure for encapsulating the sealing liquid 13 in the lens 12 is as follows. First, the lens 12 is turned upside down and the sealing liquid 13 is poured into the inner space. Next, the substrate 10 on which the light-emitting element 11 is mounted is brought, from above, close to the lens 12 with the sealing liquid 13 therein, and the lens 12 and the substrate 10 are fixed in a state in which the light-emitting element 11 is in the sealing liquid 13. The lens 12 and the substrate 10 are fixed by, e.g., a resin material such as silicone, or solder.

### Effects of the Embodiment

In the light-emitting device 1 in the embodiment of the invention, by providing the depression 121 on the lens 12, the air bubbles 15 included in the sealing liquid 13 can be kept at a position not overlapping the optical axis L of the light-emitting element 11 and a decrease in light extraction efficiency due to the air bubbles 15 can thereby suppressed.

Although the embodiment of the invention has been described, the invention is not intended to be limited to the embodiment, and the various kinds of modifications can be implemented without departing from the gist of the invention. In addition, the constituent elements in the embodiment can be arbitrarily combined without departing from the gist of the invention.

In addition, the embodiment described above does not limit the invention according to the claims. Further, please note that not all combinations of the features described in the embodiment are necessary to solve the problem of the invention.

### REFERENCE SIGNS LIST

1 LIGHT-EMITTING DEVICE
10 SUBSTRATE
11 LIGHT-EMITTING ELEMENT
12 LENS
121 DEPRESSION
122 PROTRUSION
13 SEALING LIQUID
15 AIR BUBBLE

1. A light-emitting device, comprising:
a light-emitting element mounted on a substrate;
a lens disposed on the substrate so as to cover the light-emitting element; and
a sealing liquid disposed in a space defined under the lens to seal the light-emitting element,
wherein an inner surface of the lens comprises a depression that is recessed upward at a position not overlapping an optical axis of the light-emitting element,
wherein a position of the depression is higher than a position of a point on the inner surface that is located on the optical axis, and
wherein a height of the inner surface monotonically increases from the point on the optical axis to the depression.

2. The light-emitting device according to claim 1, wherein an air bubble is included in at least a portion of the depression.

3. The light-emitting device according to claim 1, wherein the sealing liquid comprises a fluorine-based oil.

4. The light-emitting device according to claim 1, wherein the depression is provided in a position where horizontal position thereof does not overlap the light-emitting element.

5. The light-emitting device according to claim 1, wherein the depression comprises an annular planar pattern that surrounds the optical axis.

6. The light-emitting device according to claim 1, wherein the inner surface of the lens comprises a protrusion located at a position overlapping the optical axis and curved toward the light-emitting element.
